(19) United States
(12) Patent Application Publication
(10) Pub. No.: US 2024/0113170 A1
(43) Pub. Date: Apr. 4, 2024

(54) WIDE BANDGAP TRANSISTOR LAYOUT WITH STAGGERED THROUGH WAFER VIAS OUTSIDE OF TRANSISTOR LAYOUT

(71) Applicant: SKYWORKS SOLUTIONS, INC., Irvine, CA (US)

(72) Inventor: Guillaume Alexandre Blin, Carlisle, MA (US)

(21) Appl. No.: 18/373,360

(22) Filed: Sep. 27, 2023

Related U.S. Application Data
(60) Provisional application No. 63/378,324, filed on Oct. 4, 2022.
(60) Provisional application No. 63/378,276, filed on Oct. 4, 2022.
(60) Provisional application No. 63/378,278, filed on Oct. 4, 2022.

(51) Int. Cl. H01L 29/06; H01L 29/20; H01L 29/417; H01L 29/778

(52) U.S. Cl. CPC H01L 29/0692; H01L 29/2003; H01L 29/41758; H01L 29/7786

(57) ABSTRACT

Disclosed is a field effect transistor integrated within an associated transistor area, the field effect transistor comprising: a contact configuration with interleaved contact fingers including a number of source contact fingers connected to a source contact by through wafer vias staggered at alternating ends of the source contact fingers.

### CROSS-REFERENCE TO RELATED APPLICATIONS

This application claims priority under 35 U.S.C. § 119(e) to U.S. Provisional Patent Application Ser. No. 63/378,324, titled “WIDE BANDGAP TRANSISTOR LAYOUT WITH STAGGERED THROUGH WAFER VIAS OUTSIDE OF TRANSISTOR LAYOUT,” filed Oct. 4, 2022, to U.S. Provisional Patent Application Ser. No. 63/378,276, titled “WIDE BANDGAP TRANSISTOR LAYOUT WITH DRAIN ON OUTER EDGE,” filed Oct. 4, 2022, and to U.S. Provisional Patent Application Ser. No. 63/378,278, titled “WIDE BANDGAP TRANSISTOR LAYOUT WITH FOLDED GATE,” filed Oct. 4, 2022. The entire content of each of these applications is incorporated by reference herein in its entirety for all purposes.

### TECHNICAL FIELD

The present disclosure generally relates to an improved field effect transistor which can be used in radio frequency applications.

### DESCRIPTION OF RELATED TECHNOLOGY

Field effect transistors are widely used in many technical applications such as 5G telecommunication applications. Field effect transistors can be used in power amplifiers implemented in radio frequency modules of wireless devices.

### SUMMARY

In accordance with one aspect, there is provided a field effect transistor integrated within an associated transistor area, the field effect transistor comprising: a contact configuration with interleaved contact fingers including a number of source contact fingers connected to a source contact by through wafer vias staggered at alternating ends of the source contact fingers.

In some embodiments, the through wafer vias are provided outside an active transistor area of the field effect transistor.

In some embodiments, the contact configuration comprises transistor contacts including a source contact connected by through wafer vias to a number of source contact fingers, a drain contact including a number of drain contact fingers, and a gate contact including a number of gate contact fingers.

In some embodiments, each gate contact finger is provided between a source contact finger and a drain contact finger.

In some embodiments, the contact fingers of the contact configuration comprise rectangular shaped contact fingers.

In some embodiments, the field effect transistor comprises a wide bandgap transistor.

In some embodiments, the wide bandgap transistor comprises a Gallium Nitride or Silicon Carbide transistor.

In some embodiments, the field effect transistor comprises a Gallium Arsenide transistor.

In some embodiments, the field effect transistor comprises a high-electron-mobility transistor.

In some embodiments, the high-electron-mobility transistor comprises an epitaxial layer structure grown on a substrate beneath the contact configuration.

In some embodiments, the field effect transistor comprises a metal-oxide-semiconductor field effect transistor.

In accordance with another aspect, there is provided a power amplifier comprising at least one field effect transistor integrated within an associated transistor area, the field effect transistor comprising a contact configuration of interleaved contact fingers including a number of source contact fingers connected to a source contact by through wafer vias staggered at alternating ends of the source contact fingers.

In some embodiments, the through wafer vias are provided outside an active transistor area of the field effect transistor.

In some embodiments, the contact configuration comprises transistor contacts including a source contact connected by through wafer vias to a number of source contact fingers, a drain contact including a number of drain contact fingers, and a gate contact including a number of gate contact fingers.

In some embodiments, each gate contact finger is provided between a source contact finger and a drain contact finger.

In some embodiments, the contact fingers of the contact configuration comprise rectangular shaped contact fingers.

In some embodiments, the field effect transistor comprises a wide bandgap transistor.

In some embodiments, the wide bandgap transistor comprises a Gallium Nitride or a Silicon Carbide transistor.

In some embodiments, the field effect transistor comprises a Gallium Arsenide transistor.

In some embodiments, the field effect transistor comprises a high-electron-mobility transistor.

In some embodiments, the high-electron-mobility transistor comprises an epitaxial layer structure grown on a substrate beneath the contact configuration.

In some embodiments, the field effect transistor comprises a metal-oxide-semiconductor field effect transistor.

In some embodiments, the through wafer vias are provided outside an active transistor area of said field effect transistor.

In accordance with another aspect, there is provided a wireless device. The wireless device comprises a transceiver configured to process radio frequency signals, and a radio frequency module including at least one field effect transistor integrated within an associated transistor area, the at least one field effect transistor comprising a contact configuration with interleaved contact fingers including a number of source contact fingers connected to a source contact by through wafer vias staggered at alternating ends of the source contact fingers.

In some embodiments, the wireless device further comprises an antenna connected to the radio frequency module.

### BRIEF DESCRIPTION OF THE DRAWINGS

FIGS. 1A and 1B are top views to illustrate a layout of a possible exemplary embodiment of a field effect transistor according to a first aspect of the present invention in comparison to a conventional field effect transistor layout;

FIG. 2 illustrates a layout of a possible exemplary embodiment of a field effect transistor according to a second aspect of the present invention;

FIGS. 3A and 3B illustrate a further possible exemplary embodiment of a layout of a field effect transistor according to the second aspect of the present invention;

FIG. 4 illustrates a layout of a possible exemplary embodiment of a field effect transistor according to a third aspect of the present invention;

FIG. 5 shows a cross-sectional view to illustrate a possible exemplary embodiment of a field effect transistor according to the present invention;

FIG. 6 shows a further cross-sectional view to illustrate a further possible embodiment of a field effect transistor according to the present invention; and

FIG. 7 is a block diagram illustrating a possible exemplary embodiment of a wireless device according to a further aspect of the present invention.

### DETAILED DESCRIPTION OF EMBODIMENTS

The following description of certain embodiments presents various description of specific embodiments. However, the innovation described herein can be embodied in a multiple of different ways, for example, as defined and covered by the claims. In this description, reference is made to the drawings where like reference numbers can indicate identical or functionally similar elements. It will be understood that elements illustrated in the figures are not necessarily drawn to scale. Moreover, it will be understood that certain embodiments can include more elements than illustrated in a drawing and/or in a subset of the elements illustrated in a drawing. Further, some embodiments can incorporate any suitable combination of features from two or more drawings.

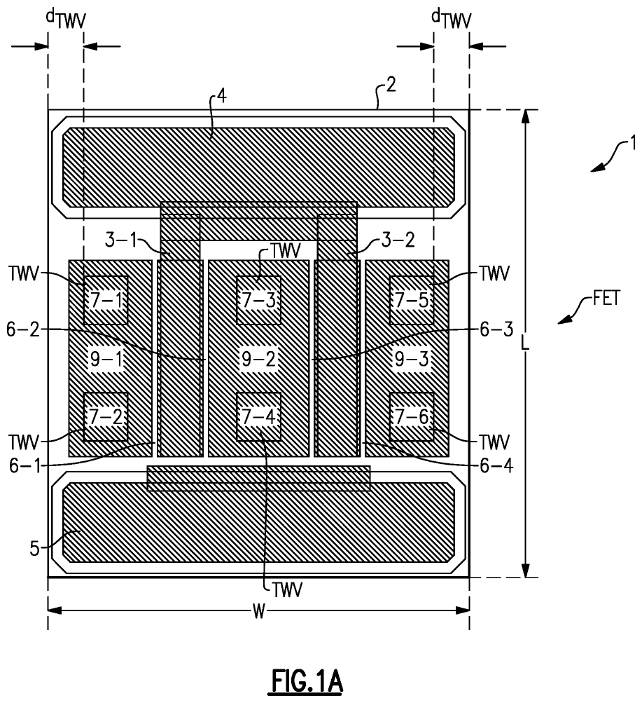

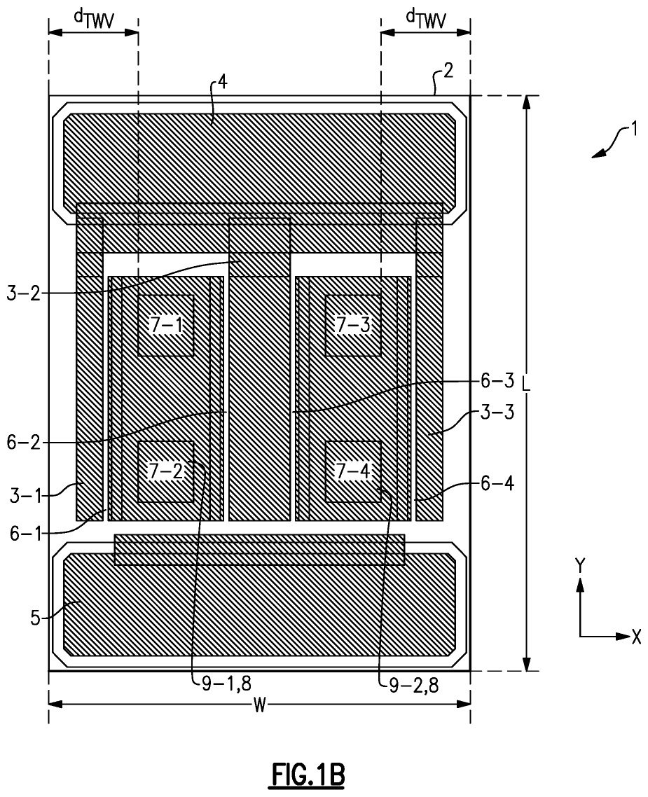

The invention provides according to a first aspect a field effect transistor 1 as illustrated in the layout of FIG. 1B. The layout of the field effect transistor 1 is illustrated in comparison to a die layout of a conventional field effect transistor as illustrated in FIG. 1A. The field effect transistor 1 illustrated in FIG. 1B according to a first aspect of the present invention is integrated within an associated transistor area 2 on a die. The field effect transistor 1 comprises transistor contacts for electrical connection to an external circuitry. The transistor contacts comprise a drain contact 4, a gate contact 5, and a source contact 8 at the back of the die (not visible in the top view of FIG. 1B).

The transistor contacts have a contact configuration of interleaved contact fingers. The interleaved contact fingers comprise in the illustrated embodiment of FIG. 1B three drain contact fingers 3-1, 3-2, 3-3. Two drain contact fingers 3-1, 3-3 are located at opposite edges of the transistor area 2 as shown in FIG. 1B. As can be seen, the drain contact fingers 3-1, 3-2, 3-3 are connected to the drain contact 4 of the field effect transistor 1. The field effect transistor 1 further comprises the gate contact 5 located on the opposite side of the transistor from the drain contact 4 as shown in FIG. 1B. The gate contact 5 includes a number of gate contact fingers 6-1, 6-2, 6-3, 6-4 electrically connected to the gate contact 5. Moreover, the field effect transistor 1 comprises a source contact 8 connected by through wafer vias (TWV) 7-1, 7-2 to a source contact finger 9-1 and connected by through wafer vias (TWV) 7-3, 7-4 to the source contact finger 9-2 as illustrated in FIG. 1B. As can be seen, each gate contact finger 6-i is provided between a source contact finger 8-i and a drain contact finger 3-i. As shown in FIG. 1B, the transistor area 2 of the integrated field effect transistor 1 comprises a width W and a length L, for instance a width W of around 500 μm and a length L of around 600 μm.

By comparing the layout of the field effect transistor 1 according to the first aspect of the present invention integrated in the associated transistor area 2 as shown in FIG. 1B to the conventional field effect transistor layout shown in FIG. 1A, it can be seen that the width W of the transistor area 2 is about 10 to 20% less than the width W of the transistor area of the conventional field effect transistor 1 shown in FIG. 1A. This is achieved since the drain contact fingers 3-i are located at opposite edges of the transistor area 2 and the through wafer vias 7-i used for connection of the source contact 8 to the number of source contact fingers 9-i are pushed further away from the die edge of the die, i.e. away from the edge of the transistor area 2 of the field effect transistor 1 as can be seen from FIGS. 1A, 1B. (Dtwv>dtwv).

The conventional field effect transistor layout illustrated in FIG. 1A comprises source contact fingers 9-i at the outer edge of the transistor area 2. Consequently, the through wafer vias 7-i connecting the source contact 8 with the source contact fingers 9-i are closer to the edge of the die as shown in FIG. 1A. Consequently, the transistor area 2 of the field effect transistor 1 according to the first aspect of the present invention provides the advantage that it occupies less space on a wafer in a manufacturing process. The die forms a small block of semiconducting material through which the given functional circuit of the field effect transistor 1 is fabricated. Integrated circuits can be produced in large batches on a single wafer in a manufacturing process. The wafer is then cut or diced into many pieces each containing a copy of the integrated circuit. The cut pieces form the die.

Besides a smaller die size, the field effect transistor 1 according to the present invention provides the further advantage that it also better balances the electrical current flowing through the through wafer vias 7-i since each through wafer via 7-i carries the electrical current of two contact fingers. As can be seen in FIG. 1A, in a conventional field effect transistor, the electrical current I flowing from the drain contact 4 through one of the two drain contact fingers 3-1,3-2 is split to flow into a source contact finger 9-1,9-3 located at the edge of the transistor area 2 and to flow into a source contact finger 9-2 located in the middle of the transistor area 2. Consequently, in the conventional layout of FIG. 1A the source contact finger 9-2 located in the center of the transistor area 2 and its through wafer vias 7-3, 7-4 have to carry twice the electrical current than each of the source contact fingers 9-1, 9-3 located on opposite sides close to the edge of the transistor area 2. In contrast, the layout of the field effect transistor 1 according to the first aspect of the present invention as illustrated in FIG. 1B is suited to balance the electrical current flowing through the through wafer vias TWVs 7-i due to the even number of source contact fingers 9-1,9-2 having an identical shape.

FIG. 1B shows only an exemplary embodiment of the field effect transistor 1 according to the first aspect of the present invention. In other embodiments, the number of interleaved contact fingers can vary. In the embodiment of FIG. 1B, the contact configuration comprises a drain contact 4 with three drain contact fingers 3-1, 3-2, 3-3. In other embodiments, there can be more drain contact fingers 3-i, even hundreds or thousands of contact fingers. In a preferred embodiment, the layout of the contact configuration is symmetrical along an axis as illustrated in FIG. 1B. Whereas the number N1 of drain contact fingers 3-i is odd (in FIG. 1B N1=3), the number N2 of source contact fingers 9-i (in FIG. 1B N2=2) and the number N3 of gate contact fingers 6-i (in FIG. 1B N3=4) is even as shown in FIG. 1B. A gate contact finger 6-i is provided between a source contact finger 9-i and a drain contact finger 3-i.

In a possible embodiment, the contact fingers of the contact configuration of the field effect transistor 1 comprise a rectangular shape as also illustrated in FIG. 1B. The width is defined in this context by the dimension of the FET contact between two adjacent fingers (in x-direction of FIG. 1B) The through wafer vias 7-i of the source contact fingers 9-i are adapted to carry equal electric current.

In a possible embodiment, the field effect transistor 1 according to the first aspect of the present invention comprises a wide bandgap transistor. This wide bandgap transistor can comprise a gallium nitride (GaN) or a silicon carbide (SiC) transistor. In a further embodiment, the field effect transistor 1 may also comprise a transistor without a wide bandgap, such as, for example, a GaAs transistor.

Wide bandgap semiconductors differ from conventional semiconductors in that they have a larger bandgap. The bandgap refers to the energy difference in the semiconductor between a top of the valence band and the bottom of the conduction band. A larger distance allows wide bandgap semiconductor power devices to operate at higher voltages, temperatures, and frequencies. A wide bandgap transistor can be used in a radio frequency power amplifier. Wide bandgap radio frequency power amplifiers such as those made from silicon carbide or gallium nitride offer improvements in bandwidth, power, and efficiency when compared to a conventional narrow bandgap transistor.

In some embodiments, the field effect transistor 1 may comprise a gallium nitride (GaN) field effect transistor. Gallium nitride field effect transistors can operate at higher temperatures and be driven with higher voltages than gallium arsenide (GaAs) transistors. The gallium nitride transistor according to the first aspect of the present invention can be integrated in a possible embodiment into a power amplifier. The field effect transistor 1 according to the first aspect of the present invention provides a high power density and high voltage breakdown. This enables the usage of the wide bandgap field effect transistor 1 having the layout as illustrated in FIG. 1B as a component within a power amplifier of a wireless device, for instance in a wireless device or a base station for a 5G application or for applications such as a radar system.

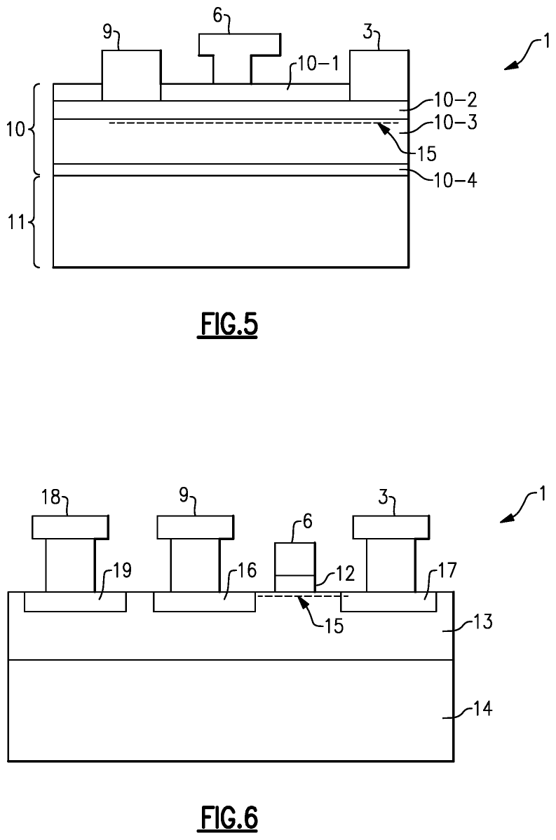

In some further embodiments of the field effect transistor 1 according to the first aspect of the present invention having the layout as illustrated in FIG. 1B, the field effect transistor 1 can comprise a high-electron-mobility transistor HEMT. A cross-section of the GaN HEMT field effect transistor is illustrated in FIG. 5. A high-electron-mobility transistor having the layout as illustrated in FIG. 1B comprises beneath the contact configuration an epitaxial layer structure 10 grown on a substrate 11. In the illustrated embodiment of FIG. 5, the contact configuration comprises a gate contact finger 6 provided between a source contact finger 9 and a drain contact finger 3. The drain contact finger 3 can be located at an edge of the transistor area 2.

Beneath the contact configuration, an epitaxial layer structure 10 is grown on the substrate 11. The epitaxial layer structure 10 comprises, in the illustrated embodiment, a thin cap layer 10-1 on top of an aluminum GaN barrier layer 10-2. The aluminum GaN barrier 10-2 is provided on a buffer layer 10-3. Beneath the buffer layer 10-3, a nucleation or a relaxation layer 10-4 as illustrated in the cross-section of FIG. 5 is provided. An evaporation process can be employed to create the transistor contacts.

The high-electron-mobility transistor (HEMT) embodiment illustrated in FIG. 5 of the field effect transistor 1 according to the first aspect of the present invention having the layout as illustrated in FIG. 1B can be used for high frequency, high power, and high temperature applications. The field effect transistor 1 occupies a small integration area when fabricated and can balance the electric current flowing through the through wafer vias 7-i.

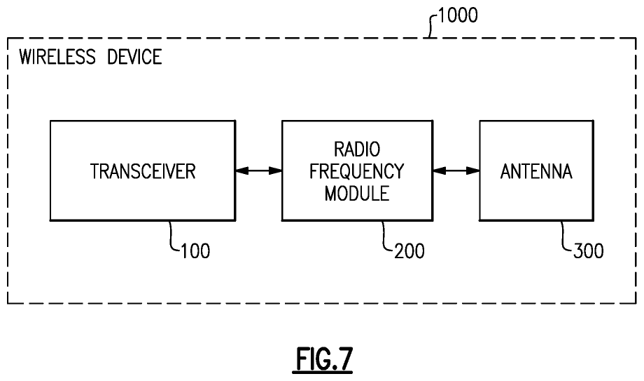

In some further embodiments, the field effect transistor 1 according to the first aspect of the present invention may also comprise a MOSFET as illustrated in the cross-sectional view of FIG. 6. The field effect transistor 1 shown in the cross-sectional view of FIG. 6 comprises a contact configuration including a gate contact finger 6 located between a source contact finger 9 and a drain contact finger 3. A dielectric layer 12 separates the gate contact finger 6 from the body layer 13 provided on top of the substrate 14. The potential on the gate contact finger 6 controls the flow of electric current through the channel 15 between the p-doped source 16 and the p-doped drain 17 as illustrated in FIG. 6. The field effect transistor 1 illustrated in FIG. 6 further comprises a body contact 18 connected to an n-doped region 19 of the body layer 13.

Whereas in the GaN HEMT field effect transistor 1 illustrated in FIG. 5 the electrically conductive channel 15 is located beneath the AlGaN barrier 10-2, the conductive channel 15 of the MOSFET 1 shown in FIG. 6 is provided beneath the gate oxide 12.

In some embodiments, the field effect transistor 1 having the layout of FIG. 1B comprises a wide bandgap transistor and can be used in a wide range of infrastructure products such as a base station, small cells, and massive MIMO (Multiple Input/Multiple Output) power amplifiers. The wide bandgap field effect transistor 1 provides a high power density so that it can comprise a smaller size and weight. It further has a high efficiency which leads to a lower power consumption and lower dissipated power or heat generation.

Further, the field effect transistor 1 implemented as a wide bandgap transistor as shown in the cross-section of FIG. 5 can provide a higher bandwidth and can provide a higher data rate. The field effect transistor 1 implemented by a wide bandgap transistor can operate at higher frequencies allowing its use in millimeter wave (FR2) applications. The field effect transistor 1 according to the first aspect of the present invention having the layout as illustrated in FIG. 1B advantageously allows minimizing the die size for a given transistor width thus increasing the efficiency of the production process significantly. The field effect transistor 1 according to the present invention can be implemented in a power amplifier.

Accordingly, a power amplifier may comprise at least one field effect transistor 1 integrated within an associated transistor area 2. The at least one field effect transistor 1 comprises transistor contacts with a contact configuration of interleaved contact fingers including outer drain contact fingers located at opposite edges of the transistor area 2 as illustrated in FIG. 1B.

The power amplifier can form part of an electronic device, in particular a wireless device as illustrated in the block diagram of FIG. 7. The wireless device 1000 shown in FIG. 7 comprises a transceiver 100 connected to a radio frequency module 200 having at least one antenna 300. The transceiver 100 is configured to process radio frequency signals. The radio frequency module 200 can include at least one field effect transistor 1 according to the present invention having the layout as illustrated in FIG. 1B. The field effect transistor 1 is integrated within an associated transistor area 2 and has a contact configuration of interleaved contact fingers including outer drain contact fingers located at opposite edges of the transistor area 2 of the respective field effect transistor 1.

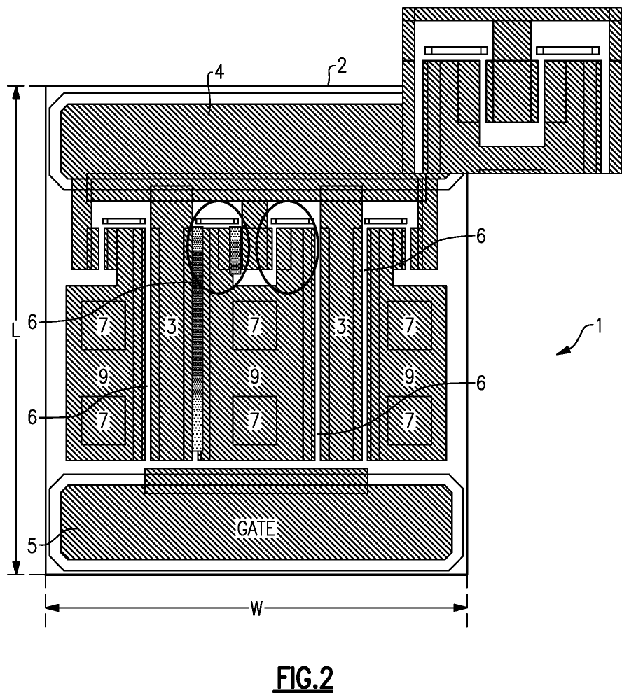

FIG. 2 illustrates a further embodiment of a field effect transistor 1 according to a second aspect of the present invention. The field effect transistor 1 according to the second aspect of the present invention comprises a so-called “folded gate.” The field effect transistor 1 is integrated within an associated transistor area 2 comprising a contact configuration with interleaved contact fingers including gate contact fingers 6, source contact fingers 9, and drain contact fingers 3.

The field effect transistor 1 according to the second aspect of the present invention has gate contact fingers 6 comprising electrically connected gate contact finger sections being distributed in the transistor area 2 as shown in FIG. 2. These distributed contact finger sections can also be referred to as a “folded gate.” The drain of each drain contact finger 3 can be connected outside the active area of the transistor so that there are several drain contact fingers 3 and several folded gates.

In a conventional field effect transistor, the temperature towards the extremities of the contact fingers tends to be lower. Due to the distribution of the gate contact finger sections, it is possible to increase the power density in this area by adding some periphery (more gate) and thus increasing the local temperature in the area where the distributed gate contact finger sections are located. The gate contact finger sections of the gate contact fingers 6 are distributed within the transistor area 2 of the field effect transistor 1 to shape a more uniform two-dimensional temperature profile in the transistor area 2 of the field effect transistor 1.

Further, the distributed contact finger sections of the gate contact fingers 6 can comprise a layout to increase thermal dissipation without increasing the peak temperature of the field effect transistor 1 in said transistor area. The provision of gate contact finger sections distributed in the transistor area 2 in fact increases the peak temperature on the edge of the contact fingers with no or minimum impact on the temperature at the center of the respective contact finger.

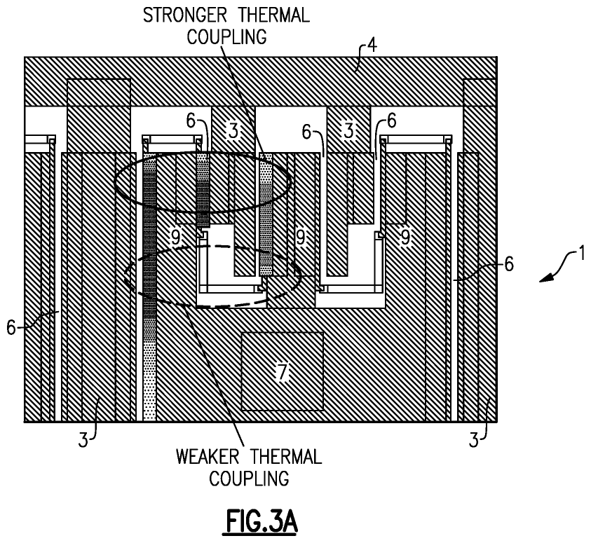

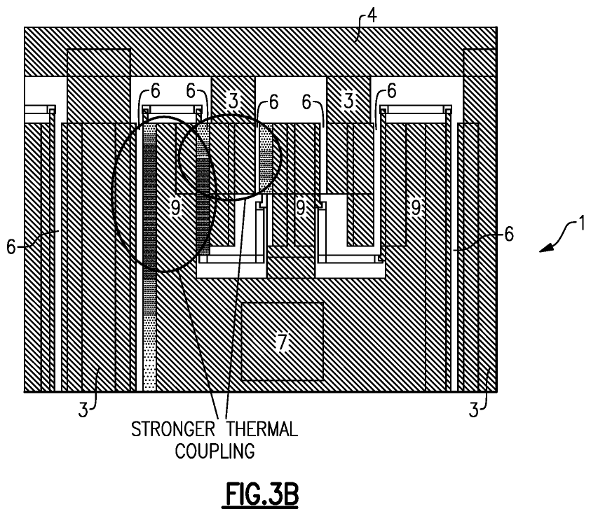

The use of a folded gate also enables a size reduction while maintaining the same operational reliability of the field effect transistor 1 due to the more uniform two-dimensional temperature profile. The gate folding can be expanded to even more gate contact fingers 6 to increase periphery and to increase locally thermal dissipation as also illustrated in FIGS. 3A and 3B. FIGS. 3A and 3B illustrate different possible exemplary embodiments of a field effect transistor 1 according to the second aspect of the present invention comprising a folded gate with distributed gate contact finger sections.

The width of the additional gate contact fingers 6 and the distance from the other contact fingers can be used as a parameter to shape the two-dimensional temperature profile of the main contact finger. The field effect transistor 1 according to the second aspect of the present invention can comprise multiple folded gates with finger-width scaling as shown in FIGS. 3A and 3B. The field effect transistor 1 according to the second aspect of the present invention can comprise a wide bandgap transistor or a transistor without a wide bandgap, such as, in particular, a GaAs transistor. In either case, field effect transistor 1 may be implemented having a cross-section as illustrated in FIG. 5. The wide bandgap transistor can comprise a GaN or a SiC transistor.

The field effect transistor 1 according to the second aspect of the present invention can also comprise in a possible embodiment a high-electron-mobility transistor HEMT having a cross-section as illustrated in FIG. 5. In an alternative embodiment, the field effect transistor 1 according to the second aspect of the present invention having the layout as illustrated in FIG. 2, FIG. 3A, or FIG. 3B can also comprise a MOSFET having a cross-section such as illustrated in FIG. 6. The field effect transistor 1 according to the second aspect of the present invention having the layout of FIG. 2, 3A, or 3B with a folded gate can also form part of a power amplifier. This power amplifier can be integrated in any electrical device, in particular, in a wireless device 1000 as illustrated in the block diagram of FIG. 7.

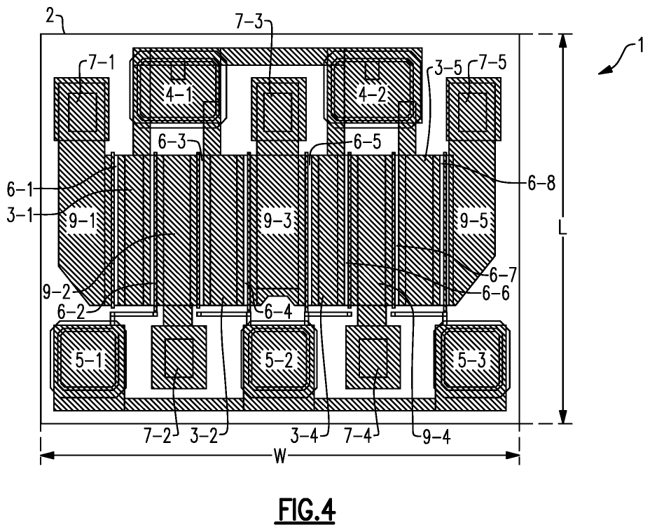

The invention further provides according to a third aspect a field effect transistor 1 having a layout as illustrated in FIG. 4. The field effect transistor 1 according to the third aspect of the present invention is integrated within an associated transistor area 2 and comprises a contact configuration with interleaved contact fingers including a number of source contact fingers 9-i connected to a source contact by through wafer vias 7-i staggered at alternating ends of the source contact fingers 9-i.

As can be seen in FIG. 4, the through wafer vias 7-i are staggered at distal ends of source contact fingers 9-i to minimize the area 2 of the field effect transistor 1. The through wafer vias 7-i are staggered alternating at a top and bottom location of the transistor area 2 as shown in FIG. 4 to allow for drain pads 4-i and gate pads 5-i. The staggered through wafer vias 7-i have the advantage that no routing crossing is required, i.e., there is no need for an air bridge or inter-dielectric layer between routing layers, in particular, between the gate and source and between the gate and drain. This facilitates the manufacturing process of the field effect transistor 1 significantly and reduces parasitic capacitance that negatively impact the RF performance such as the gain and maximum operation frequency.

The gate pitch, i.e., the distance between the gate fingers 6, is typically limited by the size of the through wafer vias metal capture section (shown in FIGS. 1A and 1B). Accordingly, it is possible to provide more equally spaced gate fingers 6 for improved thermal distribution. In an optional implementation, a gate to source parasitic capacitance reduction of the large metal bars can be achieved by shaping the bars based on the current density of the electrical current. In the illustrated implementation of FIG. 4, the layout of the field effect transistor 1 according to the third aspect of the present invention comprises five staggered through wafer vias 7-1 to 7-5 connecting the source contact fingers 9-i to the source contact. 8 The staggered through wafer vias 7-i are located outside the active field effect transistor area, i.e., the zone within the area where the active current conducting channels 15 are located.

The field effect transistor 1 according to the third aspect of the present invention having a layout such as illustrated in FIG. 4 can comprise a wide bandgap transistor including a GaN or SiC transistor. The field effect transistor 1 according to the third aspect of the present invention having the layout as illustrated in FIG. 4 can also comprise a high electron mobility transistor HEMT having a cross-section such as illustrated in FIG. 5. In a further possible embodiment, the field effect transistor 1 according to the third aspect of the present invention can also comprise a MOSFET having a cross-section such as illustrated in FIG. 6. The field effect transistor 1 according to the present invention can also form a component of a power amplifier used in a radio frequency application, in particular, in a wireless device 1000 as illustrated in the block diagram of FIG. 7.

The different aspects of the field effect transistor 1 according to the present invention may also be combined with each other. The field effect transistor 1 can be used in a wide range of electronic devices. An example of the electronic devices can include, but are not limited to consumer electronic products, infrastructure devices, audio devices, parts of consumer electronic products, or electronic test equipment. Examples of electronic devices can include but are not limited to memory chips, memory modules or other communication networks and disc driver circuits. The field effect transistor 1 according to the different aspects of the present invention is especially suited for telecommunication applications, in particular, 5G and 6G applications.

The above detailed description of embodiments of the invention is not intended to be exhaustive or to limit the invention to the precise form disclosed above. While its specific embodiments of and examples for the invention are described above for illustrative purposes, various equivalent modifications are possible within the scope of the invention, as those skilled in the relevant art will recognize. For example, while processes or blocks are presented in a given order, alternative embodiments may perform routine and may employ systems having blocks, in a different order, or some processes or blocks may be deleted, moved, added, subdivided, combined and/or modified. Each of these blocks may be implemented in a variety of different ways.

The teaching of the present invention provided herein can be applied to other systems, not necessarily the system described above. The elements and various embodiments described above can be combined to provide further embodiments.

While certain embodiments of the present invention have been described, these embodiments have been presented by way of example only, and are not intended to limit the scope of the disclosure. Indeed, the device and system described herein may be embodied in a variety of other forms. Furthermore, various omissions, substitutions and changes in the form of the system described herein may be made without departing from the spirit of the disclosure. The accompanying claims and the equivalents are intended to cover such forms or modifications as would fall within the scope and spirit of the disclosure.

What is claimed is:

1. A field effect transistor integrated within an associated transistor area, the field effect transistor comprising: a contact configuration with interleaved contact fingers including a number of source contact fingers connected to a source contact by through wafer vias staggered at alternating ends of the source contact fingers.

2. The field effect transistor of claim 1 wherein the through wafer vias are provided outside an active transistor area of the field effect transistor.

3. The field effect transistor of claim 1 wherein the contact configuration comprises transistor contacts including a source contact connected by through wafer vias to a number of source contact fingers, a drain contact including a number of drain contact fingers, and a gate contact including a number of gate contact fingers.

4. The field effect transistor of claim 3 wherein each gate contact finger is provided between a source contact finger and a drain contact finger.

5. The field effect transistor of claim 1 wherein the contact fingers of the contact configuration comprise rectangular shaped contact fingers.

6. The field effect transistor of claim 1 wherein the field effect transistor comprises a Gallium Nitride or Silicon Carbide transistor.

7. The field effect transistor of claim 1 wherein the field effect transistor comprises a Gallium Arsenide transistor.

8. The field effect transistor of claim 1 wherein the field effect transistor comprises a high-electron-mobility transistor including an epitaxial layer structure grown on a substrate beneath the contact configuration.

9. The field effect transistor of claim 1 wherein the field effect transistor comprises a metal-oxide-semiconductor field effect transistor.

10. A power amplifier comprising at least one field effect transistor integrated within an associated transistor area, the field effect transistor comprising a contact configuration of interleaved contact fingers including a number of source contact fingers connected to a source contact by through wafer vias staggered at alternating ends of the source contact fingers.

11. The power amplifier of claim 10 wherein the through wafer vias are provided outside an active transistor area of the field effect transistor.

12. The power amplifier of claim 10 wherein the contact configuration comprises transistor contacts including a source contact connected by through wafer vias to a number of source contact fingers, a drain contact including a number of drain contact fingers, and a gate contact including a number of gate contact fingers.

13. The power amplifier of claim 12 wherein each gate contact finger is provided between a source contact finger and a drain contact finger.

14. The power amplifier of claim 10 wherein the contact fingers of the contact configuration comprise rectangular shaped contact fingers.

15. The power amplifier of claim 10 wherein the field effect transistor comprises a Gallium Nitride or a Silicon Carbide transistor.

16. The power amplifier of claim 10 wherein the field effect transistor comprises a Gallium Arsenide transistor.

17. The power amplifier of claim 10 wherein the field effect transistor comprises a high-electron-mobility transistor including an epitaxial layer structure grown on a substrate beneath the contact configuration.

18. The power amplifier of claim 10 wherein the field effect transistor comprises a metal-oxide-semiconductor field effect transistor.

19. The power amplifier of claim 10 wherein the through wafer vias are provided outside an active transistor area of said field effect transistor.

20. A wireless device comprising:
a transceiver configured to process radio frequency signals;
a radio frequency module including at least one field effect transistor integrated within an associated transistor area, the at least one field effect transistor comprising a contact configuration with interleaved contact fingers including a number of source contact fingers connected to a source contact by through wafer vias staggered at alternating ends of the source contact fingers; and
an antenna connected to the radio frequency module.
